(19) United States
(12) Patent Application Publication
(10) Pub. No.: US 2009/0321816 A1
(43) Pub. Date: Dec. 31, 2009

(54) Vertical-type non-volatile memory device

(75) Inventors: Yong-Hoon Son, Yongin-si (KR); Jong-Wook Lee, Yongin-si (KR); Jun Seo, Yongin-si (KR); Jong-Hyuk Kang, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/459,148

(22) Filed: Jun. 26, 2009

(30) Foreign Application Priority Data
Jun. 27, 2008 (KR) 10-2008-0061489

(51) Int. Cl. H01L 29/792; H01L 27/088

(52) U.S. Cl. 257/326; 257/392; 257/E29.309; 257/E27.061

(57) ABSTRACT

In a vertical-type non-volatile memory device, first and second single-crystalline semiconductor pillars are arranged to face each other on a substrate. Each of the first and second single-crystalline semiconductor pillars has a rectangular parallelepiped shape with first, second, third and fourth sidewalls. A first tunnel oxide layer, a first charge storage layer and a first blocking dielectric layer are sequentially stacked on the entire surface of the first sidewall of the first single-crystalline semiconductor pillar. A second tunnel oxide layer, a second charge storage layer and a second blocking dielectric layer are sequentially stacked on the entire surface of the first sidewall of the second single-crystalline semiconductor pillar. A word line makes contact with surfaces of both the first and second blocking dielectric layers. The word line is used in common for the first and second single-crystalline semiconductor pillars.

### RELATED APPLICATION

This application claims priority under 35 U.S.C. §119 to Korean Patent Application No. 10-2008-0061489, filed on Jun. 27, 2008 in the Korean Intellectual Property Office (KIPO), the contents of which are herein incorporated by reference in their entirety.

### BACKGROUND

1. Field

Exemplary embodiments relate to a vertical-type non-volatile memory device and a method of manufacturing the same. More particularly, exemplary embodiments relate to a vertical-type non-volatile memory device capable of being highly integrated in a relatively small lateral area of a substrate and a method of manufacturing the same.

2. Description of the Related Art

Semiconductor memory devices may be applicable to various electrical and communication products. Semiconductor memory devices include integrated circuits, which may be formed by depositing a thin film on a substrate and patterning the thin film.

Recently, in order to improve the degree of integration of semiconductor memory devices, a method of forming cell transistors included in each unit chip in a vertical direction to the substrate has been researched. In particular, in the NAND-type flash memory device, one cell may include one transistor. Accordingly, the cell transistors may be stacked vertically to form a cell string, thereby improving the degree of integration thereof.

However, although the cell transistors included in the flash memory device are formed to be stacked vertically, the greater an area of the substrate required to form the cell transistors is, the less the degree of integration of the flash memory device is. In particular, because the number of cell transistors stacked vertically is limited due to various process conditions, it is necessary to reduce the area of the substrate required to form the cell transistors.

Generally, the cell transistors to be stacked vertically use a polysilicon pattern having a pillar shape as a channel region. However, cell distribution characteristics of the cell transistor using the polysilicon pattern as a channel region may be poor, and the operating speed thereof may be decreased due to the reduction of a cell current, compared with a cell transistor having a single-crystalline silicon channel. Further, when the polysilicon pattern is used as the channel region, the width of an upper portion of the polysilicon pattern may be greater than that of a lower portion of the polysilicon pattern due to a sidewall inclination angle thereof. Accordingly, the distance between the polysilicon patterns may become small, and thus it may be difficult to highly integrate the memory device.

Accordingly, recently, in order to form the cell transistor including a channel region having a pillar shape, a method of replacing the polysilicon pattern with a single-crystalline silicon pillar has been suggested. However, it may be difficult to form the single-crystalline silicon pillar with no crystal defects.

Further, in order to manufacture a highly integrated vertical-type memory device, it may be required to reduce the width of the single-crystalline silicon pillar as well as the distance between the single-crystalline silicon pillars. However, it may be not easy to form the single-crystalline silicon pillar having a small width and simultaneously reduce the distance between the single-crystalline silicon pillars.

Therefore, a highly integrated vertical-type non-volatile memory device including a single-crystalline silicon pillar having a relatively small width in a relatively small lateral area of a substrate and a method of manufacturing the same is required.

### SUMMARY

Exemplary embodiments provide a highly integrated vertical-type non-volatile memory device.

Exemplary embodiments provide a method of manufacturing the vertical-type non-volatile memory device.

Exemplary embodiments provide a method of operating the highly integrated vertical-type non-volatile memory device.

According to some exemplary embodiments, in a vertical-type non-volatile memory device, first and second single-crystalline semiconductor pillars are arranged to face each other on a substrate. Each of the first and second single-crystalline semiconductor pillars has a rectangular parallelepiped shape with first, second, third and fourth sidewalls. A first tunnel oxide layer, a first charge storage layer and a first blocking dielectric layer are sequentially stacked on the entire surface of the first sidewall of the first single-crystalline semiconductor pillar. A second tunnel oxide layer, a second charge storage layer and a second blocking dielectric layer are sequentially stacked on the entire surface of the first sidewall of the second single-crystalline semiconductor pillar. A word line makes contact with surfaces of both the first and second blocking dielectric layers. The word line is used in common for the first and second single-crystalline semiconductor pillars.

In an exemplary embodiment, the first sidewalls of the first and second single-crystalline semiconductor pillars may face each other. The second, third and fourth sidewalls may be surrounded by an insulation layer pattern.

In an exemplary embodiment, the width of the word line and the distance between the word lines may be a minimum width that can be formed through a photolithography process.

In an exemplary embodiment, a plurality of the word lines may be arranged on the first and second blocking dielectric layers to be spaced apart from one another in a vertical direction with respect to a surface of the substrate.

In an exemplary embodiment, a first group of upper select transistors and a second group of upper select transistors may be provided on the uppermost word line to face the sidewalls of the first and second single-crystalline semiconductor pillars. The first group of the upper select transistors may be serially connected to the uppermost cell transistor that is formed in the first single-crystalline semiconductor pillar. The second group of the upper select transistors may be serially connected to the uppermost cell transistor that is formed in the second single-crystalline semiconductor pillar.

Each of the first and second groups of the upper select transistors may include at least two transistors, and the first and second groups of the upper select transistors in the same layer may use the word line in common.

When transistors included in the first and second groups of the upper select transistors operate, the transistors using the word line in common may perform mutually opposite on-off actions.

The first and second groups of the upper select transistors may include a depletion-type transistor and an enhancement-type transistor.

The vertical arrangement order of the depletion-type transistor and the enhancement-type transistor formed in the first single-crystalline semiconductor pillar may be different from that of the depletion-type transistor and the enhancement-type transistor formed in the second single-crystalline semiconductor pillar.

In an exemplary embodiment, the first tunnel oxide layer, the first charge storage layer and the first blocking dielectric layer may have a linear shape extending in the same direction as the extending direction of the word line and making contact with the entire surfaces of the first sidewalls of the first single-crystalline semiconductor pillars that are arranged in the extending direction of the word line.

In an exemplary embodiment, the second tunnel oxide layer, the second charge storage layer and the second blocking dielectric layer may have a linear shape extending in the same direction as the extending direction of the word line and make contact with the entire surfaces of the first sidewalls of the second single-crystalline semiconductor pillars that are arranged in the extending direction of the word line.

According to some exemplary embodiments, in a vertical-type non-volatile memory device, a first string including first to Nth cell transistors serially connected to one another is provided. A second string is adjacent to the first string. The second string includes N+1th to 2Nth cell transistors serially connected to one another. Word lines are electrically connected to gates of the cell transistors included in the first and second strings. Each of the word lines is connected to two gates of the cell transistors included in each of the first and second strings. A first group of upper select transistors are connected to the uppermost cell transistors of the first string. A second group of upper select transistors are connected to the uppermost cell transistors of the second string. Upper select word lines are electrically connected to gates of the first and second upper select transistors. Each of the upper select word lines is connected to two gates of each of the first and second groups of the upper select transistors.

In an exemplary embodiment, each of the first and second groups of the upper select transistors may include one enhancement-type transistor and one depletion-type transistor.

The vertical arrangement order of the depletion-type transistor and the enhancement-type transistor included in the first group of the upper select transistor may be different from that of the depletion-type transistor and the enhancement-type transistor included in the second group of the upper select transistor.

According to some exemplary embodiments, in a method of manufacturing a vertical-type non-volatile memory device, a pattern structure is formed on a substrate. The pattern structure includes insulation interlayer patterns and word lines sequentially stacked on one another. A blocking dielectric layer, a charge storage layer and a tunnel oxide layer are sequentially formed on the entire surfaces of both sidewalls of the pattern structure, respectively. First and second single-crystalline semiconductor pillars are formed on a surface of the tunnel oxide layer, respectively.

In order to form the pattern structure, insulation interlayers and conductive layers for word lines may be sequentially formed on an upper surface of the substrate. The conductive layers and the conductive layers for word lines may be patterned to form the pattern structures having a line-and-space shape.

The line and space of the pattern structure may have a minimum width to be formed through a photolithography process, respectively.

In order to form the first and second single-crystalline semiconductor pillars, an amorphous silicon layer may be formed on both the sidewalls of the pattern structures, upper surfaces of the pattern structures and the surface of the substrate. The amorphous silicon layer may be anisotropically etched to form an amorphous semiconductor pattern on the substrate, the amorphous semiconductor pattern making contact with the tunnel oxide layer. An insulation layer pattern may be formed to fill a gap between the amorphous semiconductor patterns. The amorphous semiconductor pattern may be thermally treated to undergo phase transition, to form a single-crystalline semiconductor pattern. The single-crystalline semiconductor pattern may be patterned to form the first and second single-crystalline semiconductor pillars on both sidewalls of the insulation layer pattern.

The single-crystalline semiconductor pattern may be patterned using a mask pattern having a linear shape extending in a direction perpendicular to the extending direction of the pattern structure.

Thermally treating the amorphous semiconductor pattern to undergo phase transition may include irradiating a laser on the amorphous semiconductor pattern.

The method may further include forming a first group of upper select transistors and a second group of upper select transistors on the uppermost word line, the first group of the upper transistors facing the first single-crystalline semiconductor pillar, the second group of the upper transistors facing the second single-crystalline semiconductor pillar.

Each of the first and second groups of the upper select transistors may include a depletion-type transistor and an enhancement-type transistor.

The depletion-type transistor and the enhancement-type transistor may be configured such that the upper select transistors using the word line in common perform mutually opposite on-off actions when the upper select transistors operate.

The vertical arrangement order of the depletion-type transistor and the enhancement-type transistor formed in the first single-crystalline semiconductor pillar is different from that of the depletion-type transistor and the enhancement-type transistor formed in the second single-crystalline semiconductor pillar.

According to some exemplary embodiments, in a method of operating a vertical-type non-volatile semiconductor device including cell transistors respectively provided in different single-crystalline semiconductor pillars and having a bit line and word line used in common and at least two upper select transistors in each of the single-crystalline semiconductor pillars, the upper select transistor connected to a selected cell is turned on and the upper select transistor connected to the single-crystalline semiconductor pillar having the word line used in common for the selected cell is turned off. Data are read or written from or in the selected cell.

According to some exemplary embodiments, a vertical-type non-volatile memory device may include a single-crystalline semiconductor pillar formed in a relatively small lateral area of the substrate. In particular, one cell transistor in one layer may be provided in a rectangular area (2F²) having each side with twice a minimum width (F). Accordingly, a vertical type non-volatile memory device according to exemplary embodiments may be highly integrated. Further, cell transistors may be formed in a side of the single-crystalline semiconductor pillar, to thereby provide improved electrical properties.

### BRIEF DESCRIPTION OF THE DRAWINGS

The foregoing and other features and advantages of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a perspective view illustrating a non-volatile memory device in accordance with a first exemplary embodiment.

FIG. 2 is a circuit diagram illustrating the non-volatile memory device in FIG. 1.

FIGS. 3 to 11 are perspective views illustrating a method of manufacturing the non-volatile memory device in FIG. 1 in accordance with a first exemplary embodiment.

FIG. 12 is a perspective view illustrating a non-volatile memory device in accordance with a second exemplary embodiment.

FIG. 13 is a circuit diagram illustrating the non-volatile memory device in FIG. 12.

FIGS. 14 to 15 are perspective views illustrating a method of manufacturing the non-volatile memory device in accordance with a second exemplary embodiment.

FIG. 16 illustrates another embodiment of the present invention.

FIG. 17 illustrates yet another embodiment of the present invention.

FIG. 18 illustrates a further embodiment of the present invention.

FIG. 19 illustrates a still further embodiment of the present invention.

### DETAILED DESCRIPTION OF THE EMBODIMENTS

This application claims priority under 35 U.S.C. §119 to Korean Patent Application No. 2008-61489, filed on Jun. 27, 2008 in the Korean Intellectual Property Office (KIPO), the contents of which are herein incorporated by reference in their entirety.

Various exemplary embodiments will be described more fully hereinafter with reference to the accompanying drawings, in which some exemplary embodiments are shown. The present invention may, however, be embodied in many different forms and should not be construed as limited to the exemplary embodiments set forth herein. Rather, these exemplary embodiments are provided so that this description will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be described in detail with reference to the accompanying drawings.

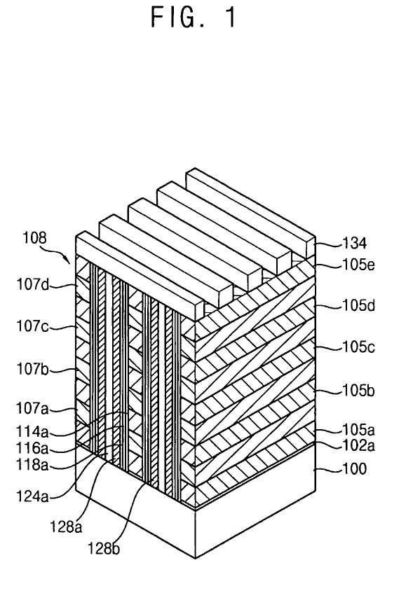

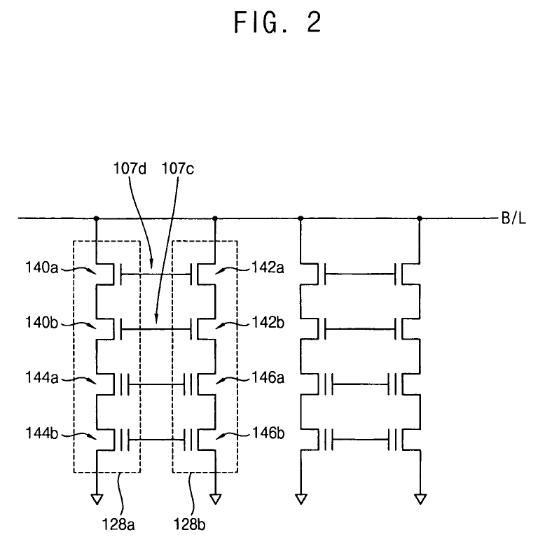

FIG. 1 is a perspective view illustrating a non-volatile memory device in accordance with a first exemplary embodiment. The non-volatile memory device of the present embodiment may be a NAND-type flash memory device. FIG. 2 is a circuit diagram illustrating the non-volatile memory device in FIG. 1.

Referring to FIGS. 1 and 2, a substrate 100 including a single-crystalline semiconductor material is provided. For example, the substrate 100 may include single-crystalline silicon.

A pad oxide layer pattern 102a is provided on the substrate 100. The pad oxide layer pattern 102a may include silicon oxide.

A pattern structure 108 is provided on the pad oxide layer pattern 102a. Insulation interlayer patterns 105a to 105e and word lines 107a to 107d are alternatively stacked to form the pattern structure 108. The pattern structure 108 may have a linear shape extending in a first direction. The pattern structures 108 may be spaced apart from one another by a predetermined distance in a second direction perpendicular to the first direction. The Insulation interlayer patterns 105a to 105e may include silicon nitride. The word lines 107a to 107d may include polysilicon. The width of the pattern structure 108 and a distance between the pattern structures 108 may be a minimum width F to be formed through a photolithography process.

The pattern structure 108 may include the same number of word lines 107a to 107e as the number of transistors stacked in a vertical direction. Each of two word lines 107c and 107d in two upper layers may be a common word line for a gate of a select transistor and each of two word lines 107a and 107b in other two layers may be a common word line for a control gate of a cell transistor.

A blocking dielectric layer pattern 114a, a charge storage layer pattern 116a and a tunnel oxide layer pattern 118a are laterally stacked on the entire surfaces of both sidewalls of the pattern structure 108. In particular, a first blocking dielectric layer pattern, a first charge storage layer pattern and a first tunnel oxide layer pattern are stacked on a first sidewall of the pattern structure 108. A second blocking dielectric layer pattern, a second charge storage layer pattern and a second tunnel oxide layer pattern are stacked on a second sidewall of the pattern structure 108 that is opposite to the first sidewall.

First semiconductor pillars 128a having isolated shapes are provided to face the first channel oxide layer pattern. The first semiconductor pillars 128a are repeatedly arranged in the extending direction of the first tunnel oxide layer pattern. Second semiconductor pillars 128b having isolated shapes are provided to face the second channel oxide layer pattern. The second semiconductor pillars 128b are repeatedly arranged in the extending direction of the second tunnel oxide layer pattern. The first and second semiconductor pillars 128a and 128b may include single-crystalline silicon. The first and second semiconductor pillars 128a and 128b may have a rectangular parallelepiped shape.

A first insulation layer pattern 124a is formed between the first and second pillars 128a and 128b in the second direction. A second insulation layer pattern (not illustrated) is formed between the first and second pillars 128a and 128b in the first direction and between the first insulation layer patterns 124a.

Thus, flash memory cell transistors are formed in the first and second semiconductor pillars 128a and 128b to be serially connected to one another in the vertical direction with respect to a surface of the substrate 100.

Two upper transistors in the first and second semiconductor pillars 128a and 128b may be provided as upper select transistors 140a, 140b, 142a and 142b. Hereinafter, the upper select transistors formed in the first semiconductor pillar 128a are referred to as a first group of upper select transistors and the upper select transistors formed in the second semiconductor pillar 128b are referred to as a second group of upper select transistors. The first group of the upper select transistors may include a first upper select transistor 140a in the uppermost layer and a second upper select transistor 140b positioned next to the first upper select transistor 140b. The second group of the upper select transistors may include a third upper select transistor 142a in the uppermost layer and a fourth upper select transistor 142b positioned next to the first upper select transistor 140b.

At least one pair of the upper select transistors of the upper select transistors using the word lines in common may perform mutually opposite on-off actions.

For example, the first upper select transistor 140a and the third upper select transistor 142a using the one word line 107d in common may perform mutually opposite on-off actions. Alternatively, the second upper select transistor 140b and the fourth upper select transistor 142b using the other word line 107c in common may perform mutually opposite on-off actions.

On the other hand, when one pair of the upper select transistors perform mutually opposite on-off actions, the other pair of the upper select transistors may perform the same on-off actions.

For this, any one of the first and second groups of the upper select transistors 140a and 140b using the word lines 107c and 107d in common may be provided as a depletion-type transistor and the other may be provided as an enhancement-type transistor.

For example, any one of the first group of the upper select transistors 140a and 140b formed in the first single-crystalline semiconductor pillar 128a may be provided as a depletion-type transistor and the other may be provided as an enhancement-type transistor. The vertical arrangement order of the depletion-type transistor and the enhancement-type transistor of the second group of the upper select transistors 142a and 142b may be different from that of the first group of the upper select transistors 140a and 140b.

For example, when the first upper select transistor 140a is provided as a depletion-type transistor, the second upper select transistor 140b and the third upper select transistor 142a may be provided as an enhancement-type transistor and the fourth upper select transistor 142b may be provided as a depletion-type transistor. Alternatively, when the first upper select transistor 140a is provided as an enhancement-type transistor, the second upper select transistor 140b and the third upper select transistor 142a may be provided as a depletion-type transistor and the fourth upper select transistor 142b may be an enhancement-type transistor.

A bit line 134 is provided to face the upper surfaces of the first and second semiconductor pillars 128a and 128b. The bit line may extend in the second direction perpendicular to the extending direction of the word lines 107a to 107d.

Although it is not illustrated in the figures, one lower select transistor may be provided in the lowermost region of each of the semiconductor pillars.

In the non-volatile memory device according to this embodiment, one cell transistor may be provided in a lateral area of 2F² and the cell transistors may be stacked in the vertical direction, to thereby highly integrate the non-volatile memory.

Hereinafter, a circuit of the non-volatile memory device in accordance with this embodiment will described with reference to FIG. 2.

As illustrated in FIG. 2, the cell transistors are serially connected to each other in each string. First and second cell transistors 144a and 144b are serially connected to each other in a first string. Third and fourth cell transistors 146a and 146b are serially connected to each other in a second string.

The word lines are provided such that two pairs of gates of the cell transistors 144a and 144b included in the first string and gates of the cell transistors 146a and 146b included in the second string are respectively connected to the word lines. That is, the gates of the first and third cell transistors 144a and 146a are connected to one word line, and the gates of the second and fourth transistors 144b and 146b are connected to the other word line.

The upper select transistors 140a, 140b, 142a and 142b are connected to the uppermost cell transistor of each of the strings. For example, the first group of the upper select transistors 140a and 140b may be connected to each other in an odd number of the strings, and the second group of the upper select transistors 142a and 142b may be connected to each other in an even number of the strings corresponding to the odd number of the strings.

Each of the first group and second group of the upper select transistors 140a, 140b, 142a and 142b may include one enhancement-type transistor and one depletion-type transistor. The vertical arrangement order of the depletion-type transistor and the enhancement-type transistor included in the first group of the upper select transistors 140a and 140b may be different from that included in the second group of the upper select transistors 142a and 142b.

For example, the first upper select transistor 140a included in the first group of the upper select transistors 140a and 140b may be an enhancement-type transistor and the second upper select transistor 140b may be a depletion-type transistor. The third upper select transistor 142a included in the second group of the upper select transistors 142a and 142b may a depletion-type transistor and the fourth upper select transistor 142b may be an enhancement-type transistor.

In the case of the non-volatile memory device illustrated in FIG. 2, unlike a conventional non-volatile memory, when reading or wiring data in a selected cell, data may be read or written together in a cell adjacent to the selected cell using the same word line in common. Accordingly, in order to read or write data only in a selected cell, a procedure of selecting any one of two strings using the same word line in common is used. One of the strings may be selected using the first to fourth upper select transistors.

An enhancement-type transistor and a depletion-type transistor are included in the first to fourth upper select transistors 140a, 140b, 142a and 142b. The enhancement-type transistor may turn on when more than threshold voltage is applied to the gate. The depletion-type transistor may turn off when threshold voltage is applied to the gate, while the depletion-type transistor may turn on if there is a channel when a voltage is applied to the gate.

In this embodiment, the enhancement-type transistor may function as a conventional select transistor and the depletion-type transistor may function as a switching device for tuning off the unselected string. Accordingly, the enhancement-type transistor and the depletion-type transistor may perform mutually opposite actions or perform the same actions based on the voltage applied to the word line.

Hereinafter, operations of the non-volatile memory device in accordance with a first exemplary embodiment will be described with reference to FIG. 2.

Since a method of selecting a string using the first to fourth upper select transistors 140a, 140b, 142a and 142b is different from a convention operation, the method of selecting the string will be described.

To read or write data in a selected cell, first, it is determined in which string the word line used in common for the selected cell is positioned.

For example, in a case that the selected cell is positioned in the first semiconductor pillar 128a, in order to select the string where the selected cell is positioned, both the first and second select transistors 140a and 140b may turn on and any one of the third and fourth select transistors 142a and 142b may turn on.

In this embodiment, because the first upper select transistor 140a is an enhancement-type transistor, a voltage may be applied to the word line 107d such that the first upper select transistor 140a is on-state. In this case, the third upper select transistor 142a using the word line 107d with the first upper select transistor 140a may be preferably off-state, but not necessarily off-state. Additionally, because the second upper select transistor 140b is a depletion transistor and the fourth upper select transistor 142b is an enhancement transistor, when a voltage is not applied to the word line 107c, the second upper select transistor 140b is on-state and the fourth upper select transistor 142b is off-state. Thus, a voltage may be applied to the word lines 107c and 107d of the first to fourth upper select transistors 140a, 140b, 142a and 142b to select the cell positioned in the first semiconductor pillar.

Alternatively, in a case that the selected cell is positioned in the second semiconductor pillar 128a, in order to select the string where the selected cell is positioned, both the third and fourth select transistors 142a and 142b may turn on and any one of the first and second select transistors 140a and 140b may turn on. In this embodiment, because the third upper select transistor 142a is a depletion transistor and the first upper select transistor 140a is an enhancement transistor, when a voltage is not applied to the word line 105c, the third upper select transistor 142a is on-state and the first upper select transistor 140a is off-state. Additionally, because the fourth upper select transistor 142b is an enhancement-type transistor, a voltage may be applied to the word line 105d such that the fourth upper select transistor 140b is on-state. In this case, the second upper select transistor 140b using the word line 107d with the fourth upper select transistor 142b may be preferably off-state, but not necessarily off-state.

Thus, any one of the strings using the word line may be selected by the aforementioned method, to write or read data in the selected cell.

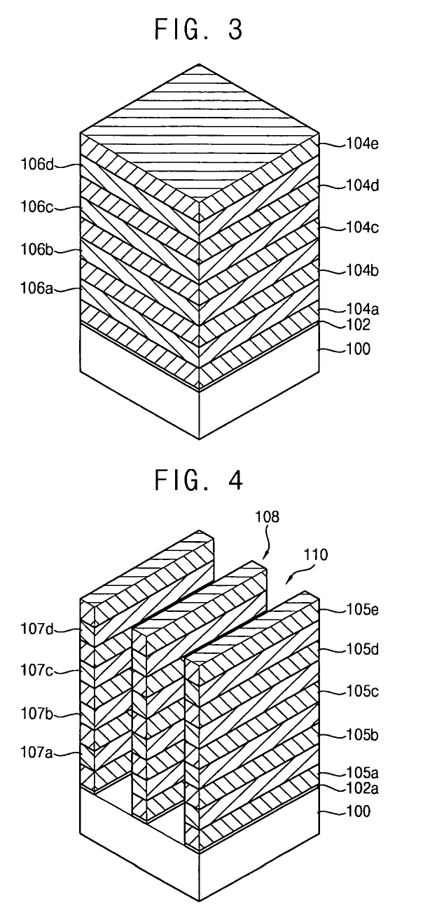

FIGS. 3 to 11 are perspective views illustrating a method of manufacturing the non-volatile memory device in FIG. 1 in accordance with a first exemplary embodiment.

Referring to FIG. 3, a substrate 100 including single-crystalline silicon is prepared. N-type impurities are partially doped into the substrate 100 to form impurity regions (not illustrated). The impurity region may be provided as a source line of a NAND-type flash memory device. The n-type impurities are doped under a surface of the substrate where one cell block is formed, to form the impurity region.

A pad oxide layer 102 is formed on the substrate 100 including the impurities therein. The substrate 100 may be thermally oxidized to form the pad oxide layer 102. The pad oxide layer 102 may be provided to reduce stress that is generated when an insulation interlayer including silicon nitride is formed directly on the substrate 100.

An insulation interlayer 104 and a conductive layer 106 are repeatedly and alternately formed on the pad oxide layer 102 in a vertical direction. The insulation interlayer 104 and the conductive layer 106 may be formed by a chemical vapor deposition (CVD) process. In this embodiment, the insulation interlayer 104 may be provided in the lowermost portion and the uppermost portion of the repeatedly stacked structure, respectively. The conductive layer 106 may include polysilicon. The insulation interlayer 104 may include silicon nitride.

The conductive layers 106 are patterned by a sequential process to be a control gate pattern in each of layers. The control gate pattern may be provided to be a word line. Accordingly, the sacrificial layers 106 may have a thickness greater than or equal to the effective length of the control gate pattern of each of the layers.

Therefore, the stacked number of the insulation interlayer 104 and the conductive layer 106 may be greater than or equal to the number of cell the transistors included in the cell string. In this embodiment, because two cell transistors and two upper selection transistors are provided in one cell string, as illustrated in the figure, first to fifth insulation interlayers 104a to 104e and first to fourth conductive layers 106a to 106d may be alternatively stacked with one another.

Referring to FIG. 4, a first photoresist pattern (not illustrated) is formed on the uppermost fifth insulation interlayer 104e. The first photoresist pattern may have a linear shape extending in the first direction.

The first to fifth insulation interlayers 104a to 104e and the first to fourth conductive layers 106a to 106d are etched using the first photoresist pattern as an etching mask until the surface of the substrate 100 is exposed, to form a pattern structure 108. The pattern structure 108 includes first to fourth conductive layers 106a to 106d, first and second control gates 107a and 107b and first and second selection gates 107c and 107d. A first opening 110 between the pattern structures formed by the etch process may provide a region for a semiconductor pillar to be formed.

In order to manufacture a highly integrated semiconductor device, the width of the pattern structure 108 and the width of the first opening 110 may be reduced to the same level of the design rule.

Alternatively, a hard mask pattern may be used as an etching mask to form the pattern structure 108.

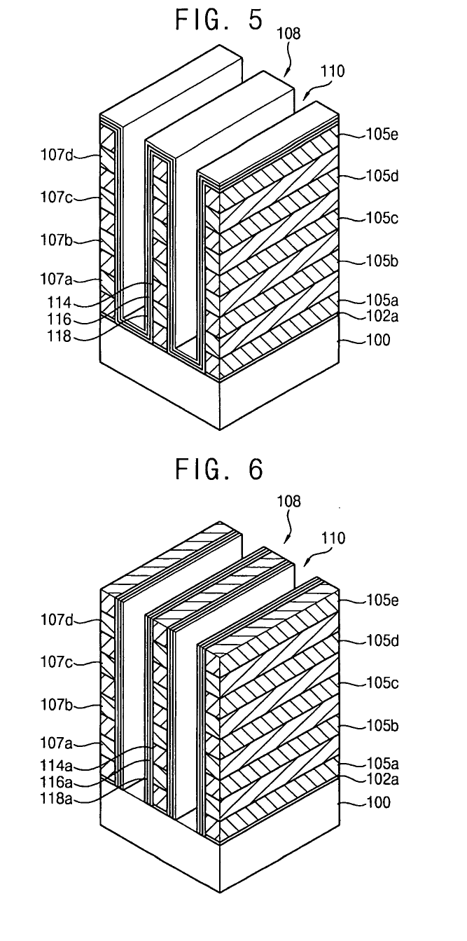

Referring to FIG. 5, a blocking dielectric layer 114, a charge storage layer 116 and a tunnel oxide layer 118 are conformally formed on the surfaces of the pattern structure 108a and the substrate 100. Here, the blocking dielectric layer 114, the charge storage layer 116 and the tunnel oxide layer 118 may have relatively small thicknesses not to completely fill the first opening 110.

The blocking dielectric layer 114, the charge storage layer 116 and the tunnel oxide layer 118 may be formed by a CVD process or an atomic layer deposition (ALD) process.

The blocking dielectric layer 114 may be formed using silicon oxide or metal oxide. For example, the blocking dielectric layer 114 may be formed using silicon oxide that can be easily etched by a dry etch process.

The charge storage layer 116 may be formed using insulating material capable of trapping an electric charge. For example, the charge storage layer 116 may include silicon nitride.

The tunnel oxide layer 118 may be formed using silicon oxide.

Referring to FIG. 6, the blocking dielectric layer 114, the charge storage layer 116 and the tunnel oxide layer 118 are anisotropically etched until the surface of the substrate 100 and an upper surface of the pattern structure are exposed, to form a tunnel oxide layer pattern 118a, a charge storage layer pattern 116a and a blocking dielectric layer pattern 114a covering the entire sidewalls of the pattern structure.

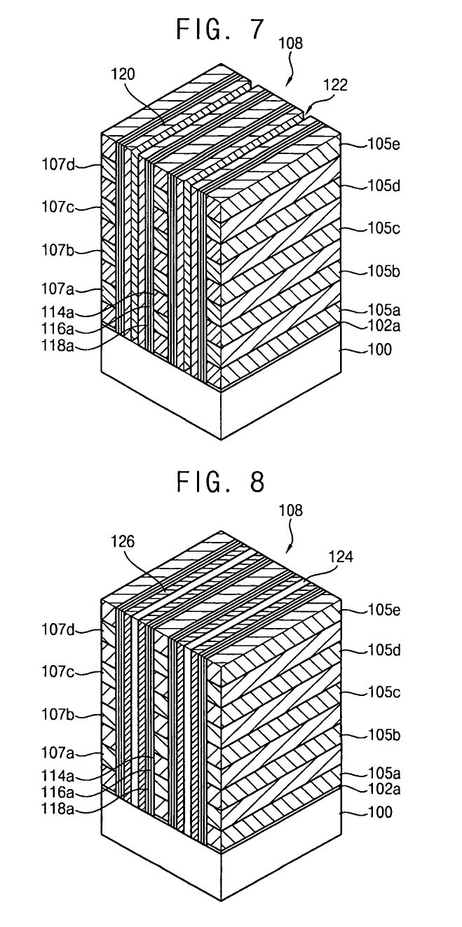

Referring to FIG. 7, an amorphous silicon layer (not illustrated) is conformally formed on the upper surface of the pattern structure 108, a surface of the tunnel oxide layer pattern 118a and the surface of the substrate 100. Here, the first opening may be not completely filled with the amorphous silicon layer. The amorphous silicon layer may be provided as a semiconductor pillar by a sequential process.

The amorphous silicon layer is anisotropically etched until the upper surface of the pattern structure 108 and the surface of the substrate 100, to form an amorphous silicon pattern 120 having a spacer shape that makes contact with the surface of the tunnel oxide layer pattern 118a. Accordingly, a second opening 122 is formed between the amorphous silicon patterns 120 to have a width smaller than that of the second opening 122.

Referring to FIG. 8, an insulation layer (not illustrated) is formed on the pattern structure to fill the second opening 122. The insulation layer may be formed using silicon oxide by a CVD process.

The insulation layer is planarized until the upper surface of the pattern structure 108 is exposed, to form a preliminary insulation layer pattern 124 within the second opening 122. The insulation layer may be planarized by a chemical mechanical polish (CMP) process.

The amorphous silicon pattern 120 (see FIG. 7) is thermally treated to form a single-crystalline silicon pattern 126.

Examples of the thermal treatment for forming the single-crystalline silicon pattern 126 may be a laser epitaxial growth (LEG) process, a solid phase transition epitaxy (SPE) process, etc. The thermal treatment may be performed using a laser, a furnace, etc. When the LEG process is performed, amorphous silicon may undergo phase transition to single-crystalline silicon in a relatively short time, to thereby reduce thermal budget.

The laser used for the thermal treatment may have an energy density sufficient to completely melt the deposited amorphous silicon. In particular, as a laser beam is irradiated on the amorphous silicon, the amorphous silicon is melted to be changed from a solid phase to a liquid phase. The phase transition occurs from the upper surface of the amorphous silicon pattern 120 to the upper surface of the substrate 100. For example, the laser beam may be irradiated at a temperature of about 1,410° C., the melting point of silicon.

Accordingly, the single crystal of the substrate 100 is used as a seed for the liquefied amorphous silicon, and thus the crystal structure of the amorphous silicon pattern 120 is changed to a single-crystalline structure. For example, an excimer laser, a kind of a gas laser, may be used in a laser member for irradiating the laser beam. The laser member may irradiate a laser beam using a scanning method, and thus the laser beam may be irradiated in a relatively short time.

While the laser beam is irradiated, the substrate 100 may be heated together. Thus, when the amorphous silicon pattern 120 undergoes a phase transition by the irradiation of the laser beam, the substrate 100 is heated together to thereby reduce a temperature gradient in a layer where the phase transition occurs. For example, when the laser beam is irradiated, the substrate 100 may be heated to about 400° C.

Thus, the laser beam is irradiated to the amorphous silicon to change the crystal structure of the amorphous silicon pattern 120 into single-crystalline silicon, to thereby form the single-crystalline silicon pattern 126 having a linear shape on the substrate 100.

When the width of the first opening is the same as the design rule, the width of the single-crystalline silicon pattern 126 may be about a third of the design rule.

Although it is not illustrated in the figure, the height of the single-crystalline silicon pattern 126 may be reduced to become less than that of the amorphous silicon pattern. Accordingly, after forming the single-crystalline silicon pattern 126, a planarization process may be further performed such that the single-crystalline silicon pattern 126 may have an even upper surface.

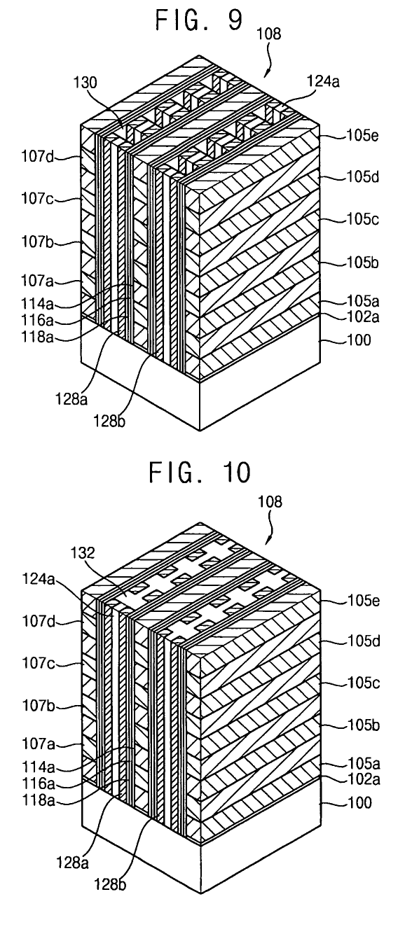

Referring to FIG. 9, a second photoresist pattern (not illustrated) is formed on the single-crystalline silicon pattern 126 and the pattern structure 108. The second photoresist pattern may have a linear shape extending in the second direction perpendicular to the first direction.

The single-crystalline silicon pattern 126 and the preliminary insulation layer pattern 124 are etched using the second photoresist pattern as an etching mask to form semiconductor pillars 128a and 128b and first insulation patterns 124a, while the pattern structure 108 is not etched. The semiconductor pillars 128a and 128b having isolated shapes are repeatedly arranged in the first direction. The first insulation layer pattern 124a is formed between the semiconductor pillars 128a and 128b in the second direction to insulate the semiconductor pillars 128a and 128b. Further, a third opening 130 is formed between the semiconductor pillars 128a and 128b arranged in the first direction.

In order to manufacture a highly integrated semiconductor device, the width of the semiconductor pillars 128a and 128b and the width between the semiconductor pillars 128a and 128b may be reduced to the same level of the design rule.

Referring to FIG. 10, an insulation layer (not illustrated) is deposited to fill the third opening 130. Then, the insulation layer is planarized until the upper surface of the pattern structure 108 is exposed, to form a second insulation layer pattern 132. The second insulation layer pattern may insulate the semiconductor pillars 128a and 128b arranged in the first direction.

By performing the aforementioned processes, transistors are formed in the semiconductor pillars 128a and 128b to be serially connected to one another in the vertical direction with respect to the substrate. Two adjacent transistors may use the word line in common. Hereinafter, one semiconductor pillar using the word lines in common is referred to as a first semiconductor pillar 128a and the other semiconductor pillar is referred to as a second semiconductor pillar 128b.

Two transistors in the upper region of each of the semiconductor pillars 128a and 128b are provided as upper select transistors. Accordingly, impurities are implanted into corresponding channel regions of the semiconductor pillars 128a and 128b to complete the upper select transistors. In particular, the upper select transistors positioned in the first pillar 128a include a depletion-type transistor and an enhancement-type transistor that are serially connected to each other. The upper select transistors positioned in the second pillar 128b include a depletion-type transistor and an enhancement-type transistor that are serially connected to each other. The vertical arrangement order in the first semiconductor pillar may be different from that in the second semiconductor pillar.

Referring to FIG. 11, a conductive layer (not illustrated) is formed to cover upper surfaces of the pattern structure 108, the semiconductor pillars 128a and 128b, the first and second insulation layer patterns 124a and 132, the tunnel oxide layer pattern 116a, the charge storage layer pattern 114a and the blocking dielectric layer pattern 112a. A mask pattern (not illustrated) is formed on the conductive layer to cover the semiconductor pillars 128a and 128b arranged in the second direction. The mask pattern may have a linear shape extending in the second direction. The mask pattern may be formed using a photoresist pattern or a hard mask pattern.

The conductive layer is etched using the mask pattern as an etching mask to form a bit line 134.

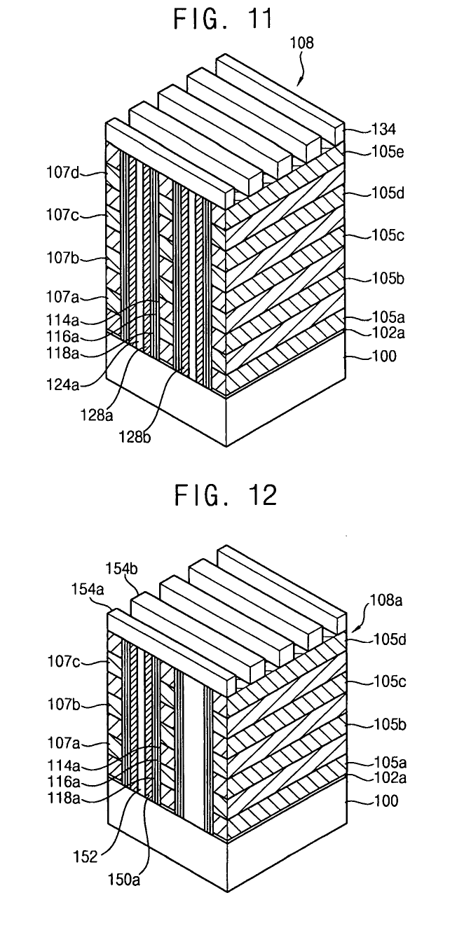

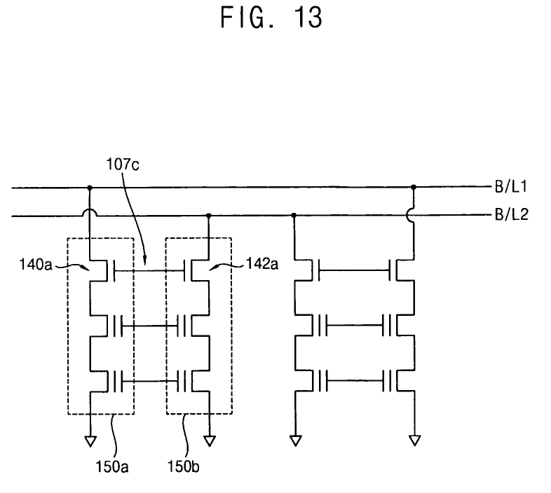

FIG. 12 is a perspective view illustrating a non-volatile memory device in accordance with a second exemplary embodiment. FIG. 13 is a circuit diagram illustrating the non-volatile memory device in FIG. 12.

Hereinafter, the same reference numerals will be used to refer to the same or like parts in the non-volatile memory device according the present embodiment as those described in Embodiment I and any further repetitive explanation concerning the above elements will be omitted.

Referring to FIGS. 12 and 13, a substrate 100 including a single-crystalline semiconductor material is provided. For example, the substrate 100 may include single-crystalline silicon.

A pad oxide layer pattern 102a is provided on the substrate 100. The pad oxide layer pattern 102a may include silicon oxide.

A pattern structure 108 is provided on the pad oxide layer pattern 102a. Insulation interlayer patterns 105a to 105e and word lines 107a to 107d are alternatively stacked to form the pattern structure 108. The pattern structure 108 may have a linear shape extending in a first direction. The pattern structures 108 may be spaced apart from one another by a predetermined distance in a second direction perpendicular to the first direction. The Insulation interlayer patterns 105a to 105e may include silicon nitride. The word lines 107a to 107d may include polysilicon. The width of the pattern structure 108 and a distance between the pattern structures 108 may be a minimum width F to be formed through a photolithography process.

The pattern structure 108 may include the same number of the word lines 107a to 107e as the number of transistors stacked in a vertical direction. One word line 107c in the uppermost layer may be a common word line for a gate of a select transistor and two word lines 107a and 107b in other two layers may be common word lines for a control gate of a cell transistor. In this embodiment, one upper select transistor may be provided differently from Embodiment I. The upper select transistor may be an enhancement-type transistor.

A blocking dielectric layer pattern 114a, a charge storage layer pattern 116a and a tunnel oxide layer pattern 118a are laterally stacked on the entire surfaces of both sidewalls of the pattern structure 108. In particular, a first blocking dielectric layer pattern, a first charge storage layer pattern and a first tunnel oxide layer pattern are stacked on a first sidewall of the pattern structure 108. A second blocking dielectric layer pattern, a second charge storage layer pattern and a second tunnel oxide layer pattern are stacked on a second sidewall of the pattern structure 108 that is opposite to the first sidewall.

First semiconductor pillars 150a are provided to face the first channel oxide layer pattern. The first semiconductor pillars 150a are repeatedly arranged in the extending direction of the first tunnel oxide layer pattern. Second semiconductor pillars 150b are provided to face the second channel oxide layer pattern. The second semiconductor pillars 150b are repeatedly arranged in the extending direction of the second tunnel oxide layer pattern. The first and second semiconductor pillars 150a and 150b may include single-crystalline silicon. The first and second semiconductor pillars 150a and 150b may have a rectangular parallelepiped shape. The first and second semiconductor pillars 150a and 150b may be arranged alternatively to each other.

An insulation layer pattern 150 is formed between the first and second pillars 150a and 150b in the second direction.

A first bit line 154a is provided on an upper surface of the first semiconductor pillar 150a. The first bit line 154a may extend in a direction perpendicular to the first direction in which the word line extends. A second bit line 154b is provided on an upper surface of the second semiconductor pillar 150b.

In this embodiment, the first and second semiconductor pillars 150a and 150b may be connected to separate bit lines 154a and 154b, respectively.

Although it is not illustrated in the figures, one lower select transistor may be provided in the lowermost region of each of the semiconductor pillars.

The non-volatile memory device according to this embodiment may have lower integration than Embodiment I. However, one upper transistor may be provided to thereby simplify constructions of peripheral circuits.

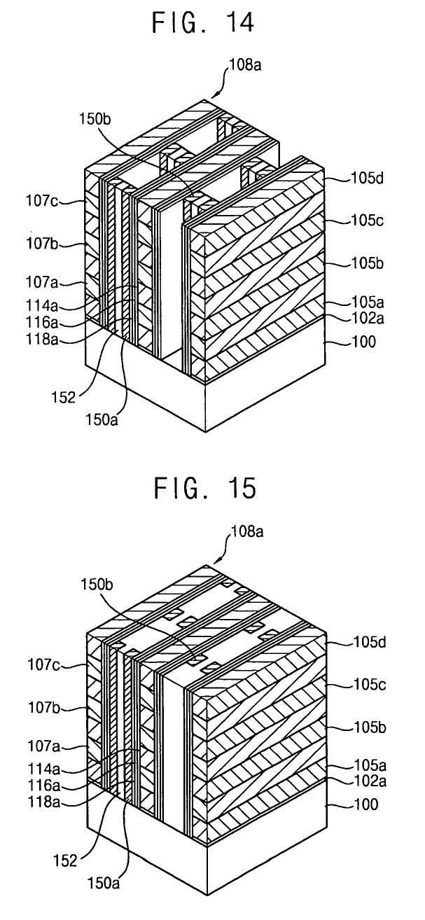

FIGS. 14 to 15 are perspective views illustrating a method of manufacturing the non-volatile memory device in accordance with a second exemplary embodiment.

The same or like processes as those described with reference to FIGS. 3 to 8 may be performed to form a single-crystalline silicon pattern in FIG. 8.

Referring to FIG. 14, a photoresist pattern (not illustrated) is formed on the single-crystalline silicon pattern 126 and the pattern structure 108 to selectively cover regions for first and second semiconductor pillars to be formed.

The single-crystalline silicon pattern 126 and the preliminary insulation layer pattern are etched using the photoresist pattern as an etching mask to form semiconductor pillars 150a and 150b, while the pattern structure 108 is not etched. The semiconductor pillars 150a and 150b having isolated shapes are arranged alternately to each other.

Referring to FIG. 15, an insulation layer (not illustrated) is deposited to fill gaps between the first and second semiconductor pillars 150a and 150b. Then, the insulation layer is planarized until the upper surface of the pattern structure is exposed, to form an insulation layer pattern 152.

Then, as illustrated in FIG. 12, a conductive layer (not illustrated) is formed to cover upper surfaces of the pattern structure 108, the semiconductor pillars 150a and 150b, the insulation layer pattern 152, the tunnel oxide layer pattern 118a, the charge storage layer pattern 116a and the blocking dielectric layer pattern 114a. A mask pattern (not illustrated) is formed on the conductive layer to cover the semiconductor pillars 150a and 150b arranged in the second direction. The mask pattern may have a linear shape extending in the second direction. The mask pattern may be formed using a photoresist pattern or a hard mask pattern.

The conductive layer is etched using the mask pattern as an etching mask to form first and second bit linen 154a and 154b.

FIG. 16 illustrates another exemplary embodiment.

As illustrated in FIG. 160, this embodiment includes a memory 510 connected to a memory controller 520. The memory 510 may be the non-volatile memory device discussed above. However, the memory 510 may be any vertical-type non-volatile memory device having the structures according to embodiments of the present invention. The memory controller 520 supplies the input signals for controlling operation of the memory 510. For example, the memory controller 520 supplies the command CMD and address ADD signals, I/O signals, etc. It will be appreciated that the memory controller 520 may control the vertical-type non-volatile memory device based on received signals.

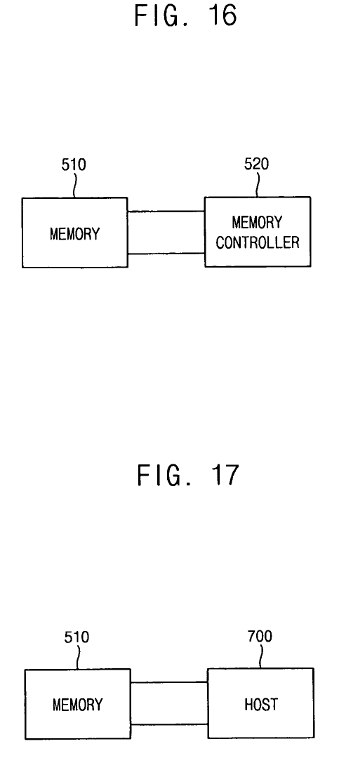

FIG. 17 illustrates yet another exemplary embodiment.

The memory 510 may be connected with a host system 700. The memory 510 may be any vertical-type non-volatile memory device having the structures according to embodiments of the present invention. The host system 700 may include an electronic product such as a personal computer, digital camera, mobile application, game machine, communication equipment, etc. The host system 700 supplies the input signals for controlling operation of the memory 510. The memory 510 is used as a data storage medium.

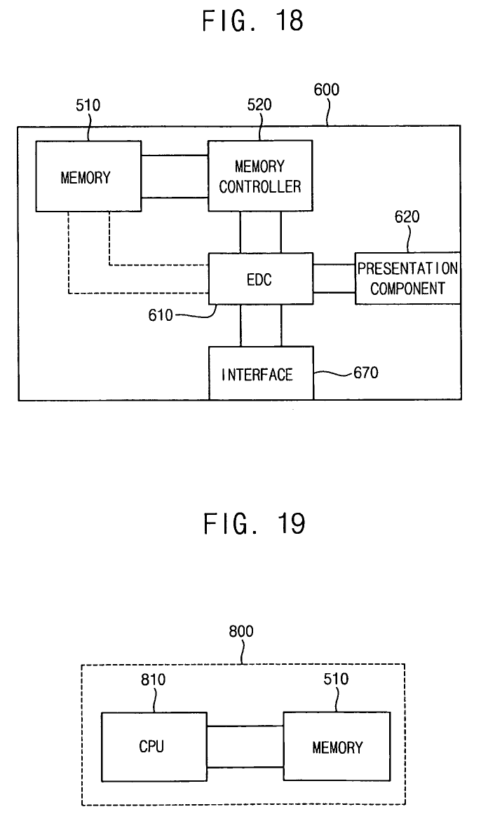

FIG. 18 illustrates a further exemplary embodiment. This embodiment represents a portable device 600. The portable device 600 may be an MP3 player, video player, combination video and audio player, etc. As illustrated, the portable device 600 includes the memory 510 and memory controller 520. The memory 510 may be any vertical-type non-volatile memory device having the structures according to embodiments of the present invention. The portable device 600 may also includes an encoder/decoder EDC 610, a presentation component 620 and an interface 670. Data (video, audio, etc.) is input to and output from the memory 510 via the memory controller 520 by the EDC 610.

FIG. 19 illustrates a still further exemplary embodiment of the present invention. As illustrated, the memory 510 may be connected to a central processing unit CPU 810 within a computer system 800. For example, the computer system 800 may be a personal computer, personal data assistant, etc. The memory 510 may be directly connected with the CPU 810, connected via BUS, etc. The memory 510 may be any vertical-type non-volatile memory device having the structures according to embodiments of the present invention. It will be appreciated that FIG. 19 does not illustrate the full complement of components that may be included within the computer system 800 for the sake of clarity.

As described above, according to exemplary embodiments, a semiconductor structure having a thin active region in a small lateral area may be provided. The semiconductor structure may be used to manufacture various semiconductor devices having an active region that extends in a vertical direction. Further, the semiconductor structure may be applied to manufacture a highly integrated semiconductor device.

The foregoing is descriptive of exemplary embodiments and is to not be construed as limiting thereof. Although a few exemplary embodiments have been described, those skilled in the art will readily appreciate that many modifications are possible in the exemplary embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is to not be construed as limited to the specific exemplary embodiments described, and that modifications to the described exemplary embodiments, as well as other exemplary embodiments, are intended to be included within the scope of the appended claims.

1. A non-volatile memory device, comprising:
first and second single-crystalline semiconductor pillars arranged to face each other on a substrate, each of the first and second single-crystalline semiconductor pillars having a rectangular parallelepiped shape with first, second, third and fourth sidewalls;
a first tunnel oxide layer, a first charge storage layer and a first blocking dielectric layer sequentially stacked on the entire surface of the first sidewall of the first single-crystalline semiconductor pillar;
a second tunnel oxide layer, a second charge storage layer and a second blocking dielectric layer sequentially stacked on the entire surface of the first sidewall of the second single-crystalline semiconductor pillar; and
a word line making contact with surfaces of both the first and second blocking dielectric layers, the word line being used in common for the first and second single-crystalline semiconductor pillars.

2. The non-volatile memory device of claim 1, wherein the first sidewalls of the first and second single-crystalline semiconductor pillars face each other.

3. The non-volatile memory device of claim 2, wherein the second, third and fourth sidewalls are surrounded by an insulation layer pattern.

4. The non-volatile memory device of claim 1, wherein the width of the word line and the distance between the word lines are a minimum width formable via a photolithography process.

5. The non-volatile memory device of claim 1, wherein a plurality of the word lines is arranged on the first and second blocking dielectric layers to be spaced apart from one another in a vertical direction with respect to a surface of the substrate.

6. The non-volatile memory device of claim 1, wherein a first group of upper select transistors and a second group of upper select transistors are provided on the uppermost word line to face the sidewalls of the first and second single-crystalline semiconductor pillars, the first group of the upper select transistors being serially connected to the uppermost cell transistor that is formed in the first single-crystalline semiconductor pillar, the second group of the upper select transistors being serially connected to the uppermost cell transistor that is formed in the second single-crystalline semiconductor pillar.

7. The non-volatile memory device of claim 6, wherein each of the first and second groups of the upper select transistors comprises at least two transistors, and the first and second groups of the upper select transistors in the same layer use the word line in common.

8. The non-volatile memory device of claim 7, wherein, when transistors included in the first and second groups of the upper select transistors operate, the transistors using the word line in common perform mutually opposite on-off actions.

9. The non-volatile memory device of claim 6, wherein the first and second groups of the upper select transistors comprise a depletion-type transistor and an enhancement-type transistor.

10. The non-volatile memory device of claim 9, wherein the vertical arrangement order of the depletion-type transistor and the enhancement-type transistor formed in the first single-crystalline semiconductor pillar is different from that of the depletion-type transistor and the enhancement-type transistor formed in the second single-crystalline semiconductor pillar.

11. The non-volatile memory device of claim 1, wherein the first tunnel oxide layer, the first charge storage layer and the first blocking dielectric layer have a linear shape extending in the same direction as the extending direction of the word line and making contact with the entire surfaces of the first sidewalls of the first single-crystalline semiconductor pillars that are arranged in the extending direction of the word line.

12. The non-volatile memory device of claim 1, wherein the second tunnel oxide layer, the second charge storage layer and the second blocking dielectric layer have a linear shape extending in the same direction as the extending direction of the word line and make contact with the entire surfaces of the first sidewalls of the second single-crystalline semiconductor pillars that are arranged in the extending direction of the word line.

13-23. (canceled)

24. A non-volatile memory device, comprising:
a first string including first to Nth cell transistors serially connected to one another;
a second string adjacent to the first string, the second string including N+1th to 2Nth cell transistors serially connected to one another;
word lines electrically connected to gates of the cell transistors included in the first and second strings, each of the word lines being connected to two gates of the cell transistors included in each of the first and second strings;
a first group of upper select transistors connected to the uppermost cell transistors of the first string;
a second group of upper select transistors connected to the uppermost cell transistors of the second string; and
upper select word lines electrically connected to gates of the first and second upper select transistors, each of the upper select word lines connected to two gates of each of the first and second groups of the upper select transistors.

25. The non-volatile memory device of claim 24, wherein each of the first and second groups of the upper select transistors comprises one enhancement-type transistor and one depletion-type transistor.

26. The non-volatile memory device of claim 25, wherein the vertical arrangement order of the depletion-type transistor and the enhancement-type transistor included in the first group of the upper select transistor is different from that of the depletion-type transistor and the enhancement-type transistor included in the second group of the upper select transistor.
